(19) United States
(12) Patent Application Publication
(10) Pub. No.: US 2015/0059173 A1
(43) Pub. Date: Mar. 5, 2015

(54) METHOD FOR MANUFACTURING MULTI-LAYERED PRINTED CIRCUIT BOARD

(71) Applicant: SAMSUNG ELECTRO-MECHANICS CO., LTD., Suwon-Si (KR)

(72) Inventors: Youn Gyu Han, Suwon-si (KR); Dong Kyoung Lee, Suwon-Si (KR)

(73) Assignee: SAMSUNG ELECTRO-MECHANICS CO., LTD., Suwon-Si (KR)

(21) Appl. No.: 14/294,701

(22) Filed: Jun. 3, 2014

(30) Foreign Application Priority Data
Aug. 27, 2013 (KR) 10-2013-0101932

(51) Int. Cl. H05K 3/46

(52) U.S. Cl. CPC H05K 3/4685; H05K 3/4644; H05K 2203/0353
USPC 29/852

(57) ABSTRACT

Disclosed herein is a method for manufacturing a multi-layered printed circuit board, the method including: an operation of preparing a substrate having an insulating layer and a surface-treated copper foil sequentially formed on an inner layer circuit; an operation of forming a hole exposing the insulating layer by performing a primary processing for the surface-treated copper foil and a part of the insulating layer with laser; and an operation of forming a through-hole exposing the inner layer circuit by performing a secondary processing for the exposed insulating layer with a chemical etching liquid.

### CROSS REFERENCE TO RELATED APPLICATION

This application claims the benefit of Korean Patent Application No. 10-2013-0101932, filed on Aug. 27, 2013, entitled “Method for Manufacturing Multi-Layered Printed Circuit Board”, which is hereby incorporated by reference in its entirety into this application.

### BACKGROUND OF THE INVENTION

1. Technical Field

The present invention relates to a method for manufacturing a multi-layered printed circuit board.

2. Description of the Related Art

In accordance with miniaturization, lightness, and high-performance of an electronic device, reduction in a circuit width and a small-caliber of a via hole connecting layers to each other have been demanded.

It is very difficult to form a hole having a diameter of about 200 μm or less using a mechanical drill. The reason is that process speed is relatively slow, process accuracy is low, product characteristics is likely to be changed due to thermal diffusion, and defect is caused by abrasion of drill bits.

Due to these disadvantages, laser has been used in forming the hole having a small-caliber.

There were many attempts to machine a copper foil with the laser, but it was difficult to form the hole in a thick copper foil since the copper foil has low laser absorption coefficient and an outer layer of the copper foil reflects the laser. As a method for manufacturing a multi-layered printed circuit board in order to solve this problem, first, a hole having the same size as a via is removed from a position of the via hole of the copper foil using an etching method and a position of an exposed insulation layer is machined with the laser.

In this case, multiple reflections and absorptions occur in a depth direction of the position of the exposed insulation layer, such that the hole is formed while resin is fused.

However, this manufacturing method degrades production efficiency due to the increased etching processes.

Second, there is a method for coating an insulating resin layer on both surfaces of an inner layer circuit, processing the via hole with the laser, and then forming the outer layer with copper plating. In this case, there was a disadvantage in that adhesion strength between the outer layer formed with the copper plating and the insulation layer became low.

Third, there is an existing method for processing the via hole by radiating the laser on a thin copper foil having a thickness of 4 μm or less. This proposes a method in which the copper foil for processing the hole is formed to be thin and the copper foil is bored at a time by using laser having high energy, but does not disclose a specific example about a method for controlling reflection. Therefore, this method has low generality.

### PRIOR ART DOCUMENT

### Patent Document

(Patent Document 1) Japanese Patent Laid-Open Publication No. 2001-251054
(Patent Document 2) Japanese Patent Laid-Open Publication No. 2002-198659

### SUMMARY OF THE INVENTION

In order to solve the problems as mentioned-above, processes according to preferred embodiments of the present invention are used.

The present invention has been made in an effort to provide a method capable of performing a primary hole process by laser process from a copper foil surface-treated to increase absorption coefficient of laser and preventing degradation of a resin and damage to an inner circuit which may be generated during a hole formation by a secondary hole process using a chemical etching liquid.

In addition, surface roughness of a hole wall surface formed by the chemical etching liquid of the secondary hole process used in the present invention provides anchor effect increasing adhesion of copper plating.

In addition, a copper foil of a multi-layered printed circuit board according to a preferred embodiment of the present invention, which is a composite copper foil having a high laser absorption coefficient, and excellent adhesion property with an insulating resin, excellent heat-resisting property, and excellent chemical resistance, provides a method for treating a surface of the copper foil.

According to a preferred embodiment of the present invention, there is provided a method for manufacturing a multi-layered printed circuit board, the method including: an operation of preparing a substrate having an insulating layer and a surface-treated copper foil sequentially formed on an inner layer circuit; an operation of forming a hole exposing the insulating layer by performing a primary processing for the surface-treated copper foil and a part of the insulating layer with laser; and an operation of forming a through-hole exposing the inner layer circuit by performing a secondary processing for the exposed insulating layer with a chemical etching liquid.

The operation of preparing the substrate may include: an operation of preparing a printed circuit board including the inner layer circuit; an operation of laminating the insulating layer on the printed circuit board; and an operation of laminating the surface-treated copper foil on the insulating layer.

The surface-treated copper foil may be formed by: an operation of applying triazole compound on a support layer to form an organic delamination layer and forming a nickel layer on the organic delamination layer at a thin thickness of 0.08 to 2 μm by electroplating; an operation of forming a copper bulk layer having a thickness of 1 to 3 μm on the nickel layer by surface-treating with the electroplating; an operation of attaching copper particles on the copper bulk layer to thereby form a copper nodule layer; an operation of forming a metal layer consisting of zinc, nickel, or a combination thereof in the copper nodule layer; an operation of forming a chromate layer on the metal layer; and an operation of forming a silane compound in the chromate layer.

The laser used in the primary processing forming the hole may be at least one of CO₂, YAG/UV, Pico, and excimer laser.

The chemical etching liquid used in the secondary processing forming the hole may be one or a mixture of two or more of hydroxyl radical, concentrated sulfuric acid, sulfate radical, ozone, sodium peroxysulfate, hydrogen peroxide, potassium permanganate, sodium salts permanganate, and chromic acid.

The method may further include, after the operation of forming the through-hole, an operation of forming a seed layer on the surface-treated copper foil of the substrate having the through-hole formed therein.

The operation of forming the seed layer may include: an operation of performing a desmear process to thereby remove residue; and an operation of forming the seed layer on a surface of the substrate in which the residue is removed by electroless plating.

The method may further include, after the operation of forming the seed layer, an operation of filling the through-hole with the electroplating.

According to another preferred embodiment of the present invention, there is provided a method for manufacturing a multi-layered printed circuit board, the method including: an operation of preparing a substrate having an insulating layer and a surface-treated copper foil sequentially formed on an inner layer circuit; an operation of forming a hole by performing a primary processing for the surface-treated copper foil and a part of the insulating layer with laser; and an operation of forming a radiation hole by performing a secondary processing for the insulating layer in the primarily processed hole with a chemical etching liquid and removing another part of the partially removed insulating layer to thereby expose the insulating layer.

The operation of preparing the substrate may include: an operation of preparing a printed circuit board including the inner layer circuit; an operation of laminating the insulating layer on the printed circuit board; and an operation of laminating the surface-treated copper foil on the insulating layer.

The surface-treated copper foil may be formed by: an operation of applying triazole compound on a support layer to form an organic delamination layer and forming a nickel layer on the organic delamination layer at a thin thickness of 0.08 to 2 μm by electroplating; an operation of forming a copper bulk layer having a thickness of 1 to 3 μm on the nickel layer by surface-treating with the electroplating; an operation of attaching copper particles on the copper bulk layer to thereby form a copper nodule layer; an operation of forming a metal layer consisting of zinc, nickel, or a combination thereof in the copper nodule layer; an operation of forming a chromate layer on the metal layer; and an operation of forming a silane compound in the chromate layer.

The laser used in the primary processing forming the hole may be at least one of CO₂, YAG/UV, Pico, and excimer laser.

The chemical etching liquid used in the secondary processing forming the hole may be one or a mixture of two or more of hydroxyl radical, concentrated sulfuric acid, sulfate radical, ozone, sodium peroxysulfate, hydrogen peroxide, potassium permanganate, sodium salts permanganate, and chromic acid.

The method may further include, after the operation of forming the radiation hole, an operation of forming a seed layer on the surface-treated copper foil of the printed circuit board having the radiation hole formed therein.

The operation of forming the seed layer may include: an operation of performing a desmear process to thereby remove residue; and an operation of forming the seed layer on a surface of the printed circuit board in which the residue is removed by electroless plating.

The method may further include, after the operation of forming the seed layer, an operation of filling the radiation-hole with the electroplating.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a cross-sectional view schematically showing a structure of a multi-layered printed circuit board according to a preferred embodiment of the present invention;

FIG. 2 is an enlarged perspective view of a part A of FIG. 1;

FIG. 3 is a cross-sectional view of a multi-layered printed circuit board in which a primary laser process is performed according to the preferred embodiment of the present invention;

FIG. 4 is a cross-sectional view showing a multi-layered printed circuit board having a hole formed therein according to another preferred embodiment of the present invention;

FIG. 5 is an enlarged perspective view of a part B of FIG. 4;

FIG. 6 is a cross-sectional view of a multi-layered printed circuit board in which a through-hole is formed with a secondary chemical etching liquid processing according to the preferred embodiment of the present invention;

FIG. 7 is a cross-sectional view of a multi-layered printed circuit board in which the through-hole is formed and a seed layer is then formed according to the preferred embodiment of the present invention;

FIG. 8 is a cross-sectional view of a multi-layered printed circuit board in which the through-hole is filled with electroplating after the forming of the seed layer according to the preferred embodiment of the present invention;

FIG. 9 is a cross-sectional view schematically showing a structure of a multi-layered printed circuit board according to another preferred embodiment of the present invention;

FIG. 10 is an enlarged perspective view of a part C of FIG. 9;

FIG. 11 is a cross-sectional view of a multi-layered printed circuit board in which a primary laser processing is performed according to another preferred embodiment of the present invention;

FIG. 12 is a cross-sectional view showing a multi-layered printed circuit board having a hole formed therein according to another preferred embodiment of the present invention;

FIG. 13 is a cross-sectional view of a multi-layered printed circuit board in which a radiation hole is formed with a secondary chemical etching liquid processing according to another preferred embodiment of the present invention;

FIG. 14 is a cross-sectional view of a multi-layered printed circuit board in which the radiation hole is formed and a seed layer is then formed according to another preferred embodiment of the present invention; and

FIG. 15 is a cross-sectional view of a multi-layered printed circuit board in which the radiation hole is filled with electroplating after the forming of the seed layer according to another preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the accompanying drawings.

### Method for Manufacturing Multi-Layered Printed Circuit Board

### First Preferred Embodiment

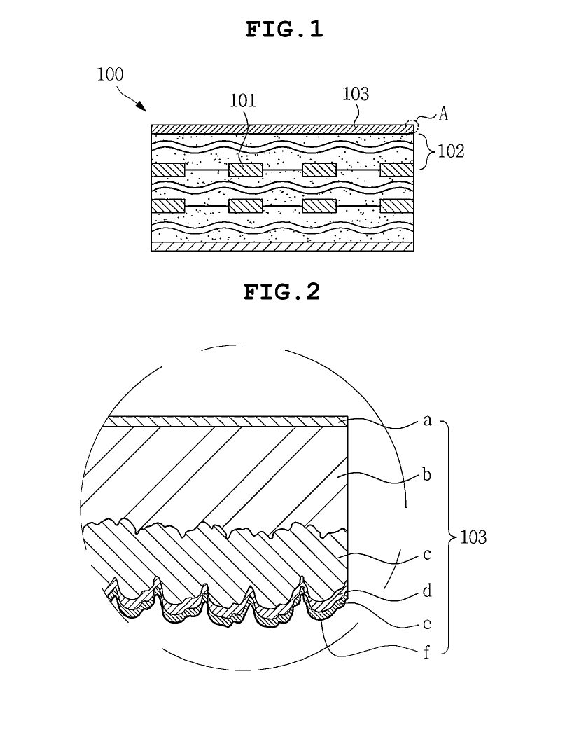

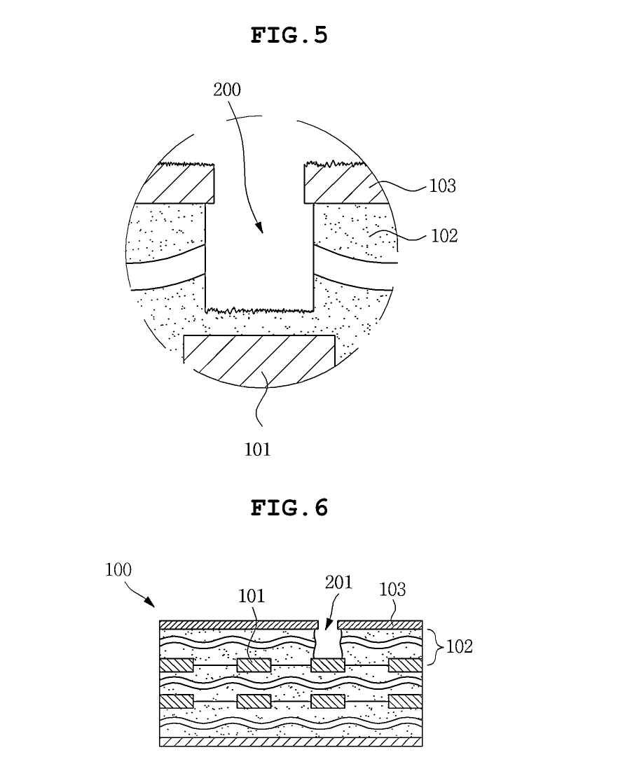

FIGS. 1 to 8 are process flow charts schematically showing a method for manufacturing a multi-layered printed circuit board according to a preferred embodiment of the present invention and processes of forming a through-hole 201 by a two-step processing may be confirmed therefrom.

According to the preferred embodiment of the present invention, the method for manufacturing the multi-layered printed circuit board may include an operation of preparing a substrate 100 having an insulating layer 102 and a surface-treated copper foil 103 sequentially formed on an inner layer circuit 101, an operation of forming a hole 200 exposing the insulating layer 102 by performing a primary processing for the surface-treated copper foil 103 and a part of the insulating layer 102 with laser, and an operation of forming a through hole 201 exposing the inner layer circuit 101 by performing a secondary processing for the exposed insulating layer 102 with a chemical etching liquid.

Referring to FIG. 1, the operation of preparing the substrate 100 may include an operation of preparing a printed circuit board including the inner layer circuit 101, an operation of laminating the insulating layer 102 on the printed circuit board, and an operation of laminating the surface-treated copper foil 103 on the insulating layer 102.

Here, the substrate 100, which is a circuit substrate on which at least one layer of circuit including a connection pad is formed on the insulating layer, may be a printed circuit board.

Although a configuration of a specific inner layer circuit is omitted in FIG. 1 for convenience of explanation, it may be easily appreciated by those skilled in the art that a typical printed circuit board having at least one layer of circuit formed on the insulating layer may be used as the substrate 100.

As the insulating layer, a resin insulating layer may be used. As a material of the resin insulating layer, a thermo-setting resin such as an epoxy resin, a thermo-plastic resin such as a polyimide resin, a resin having a reinforcement material such as a glass fiber or an inorganic filler impregnated in the thermo-setting resin and the thermo-plastic resin, for example, a prepreg may be used. In addition, a thermo-setting resin, a photo-curable resin, and the like, may be used. However, the material of the resin insulating layer is not specifically limited thereto. When cutting a cross-section of the insulating layer, the reinforcement material may be exposed.

The circuit layer may be used without being limited as long as it is used as a conductive metal for a circuit in a field of a circuit board. In the printed circuit board, copper may be typically used.

The inner layer circuit 101 according to the preferred embodiment of the present invention may be a circuit layer formed to have a thickness 0.5 to 40 μm on the copper foil by plating.

Referring to FIG. 2, which is an enlarged view of a part A of FIG. 1, a sequential process order of the following operations a to f, which is an operation of forming the surface-treated copper foil 103 may be appreciated.

a) As an operation of applying triazole compound on a support layer to form an organic delamination layer and forming a nickel layer on the organic delamination layer at a thin thickness of 0.08 to 2 μm by electroplating, delamination property between the support layer and the surface-treated copper foil is increased. The organic delamination layer and the nickel layer 130-a may decrease reflectivity and increase an accuracy of hole processability.

b) As an operation of forming a copper bulk layer 103-b having a thickness of 1 to 3 μm on the nickel layer by surface-treating with the electroplating, a copper content is highest and the copper content of the surface-treated copper foil 103 may be 90% or more.

c) An operation of attaching copper particles on the copper bulk layer 103-b to form a copper nodule layer 103-c allows the copper particles stacked on the bulk layer to be stuck in the insulating layer to thereby increase adhesion property with an insulating material.

d) As an operation of forming a metal layer 103-d consisting of zinc, nickel, or a combination thereof in the copper nodule layer 103-c, heat-resisting property and hydrochloric acid-resisting property of the copper nodule layer may be increased.

e) An operation of forming chromate layer 103-e on the metal layer 103-d increases anti-tarnish property.

f) In an operation of forming a silane compound in the chromate layer 103-e, a silane layer 103-f improving physical and chemical coupling with the insulating material may be formed.

A method for surface-treating the surface-treated copper foil 103 is basically performed in a water tank including metallic salts and may adjust a concentration pH, a temperature, and a current density of the metallic salt to thereby form the copper foil at a desired thickness.

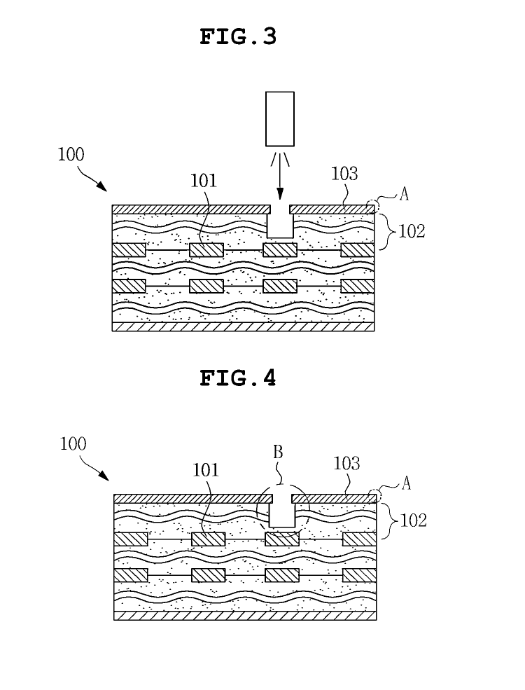

Referring to FIGS. 3 to 5, as an operation of forming a hole 200 performing a primary processing for the surface-treated copper foil 103 and a part of the insulating layer 102 with the laser to thereby expose the insulating layer 102, the hole 200 is processed without causing thermal damage to the resin and damage to the inner layer circuit 101 by adjusting energy of the laser so as not to be too high. Specifically, the hole 200 is bored using the laser while the insulating layer 102 of 0.2 to 5 μm, for example, is left on the inner layer circuit 101. The energy may be adjusted by changing laser power, repetition rate, and a spot size.

In the operation of forming the hole 200 of the method for manufacturing the printed circuit board, the laser processing may rapidly form the hole 200 in an organic material such as an epoxy resin, a polyimide resin, or the like, such that it has been widely used in manufacturing the multi-layered printed circuit board. However, since the existing copper foil surface reflects laser beam, the method for surface-treating the copper foil for solving this problem has been proposed in the present invention.

The primary laser processing of the present invention may use CO₂, YAG/UV, Pico, and excimer lasers, but the present invention does not particularly limit the kind of lasers.

Here, the operation of forming the hole 200 may be performed by setting a laser processing condition so that the surface roughness of the inner layer circuit 101 is 0.05 to 0.6 m.

In addition, the operation of forming the hole 200 is performed by setting the processing condition to a degree which does not damage the inner layer circuit 101, and a thickness of an unprocessed resin becomes generally a thickness of a butter coat of about 0.2 to 5 μm. The butter coat refers to a resin layer of a part of the insulating material including glass fabric and is the resin layer from a surface of the glass fabric to a surface of the insulating material.

Referring to FIG. 6, the operation of forming the through-hole 201 exposing the inner layer circuit 101 by performing the secondary processing for the exposed insulating layer 102 with the chemical etching liquid is included.

In the secondary processing by the chemical etching liquid, hydroxyl radicals, concentrated sulfuric acid, sulfate radical, ozone, sodium peroxysulfate, hydrogen peroxide, (potassium or sodium salts) permanganate, chromic acid, or the like having strong oxidizing power may be used, but potassium permanganate may be used for process efficiency.

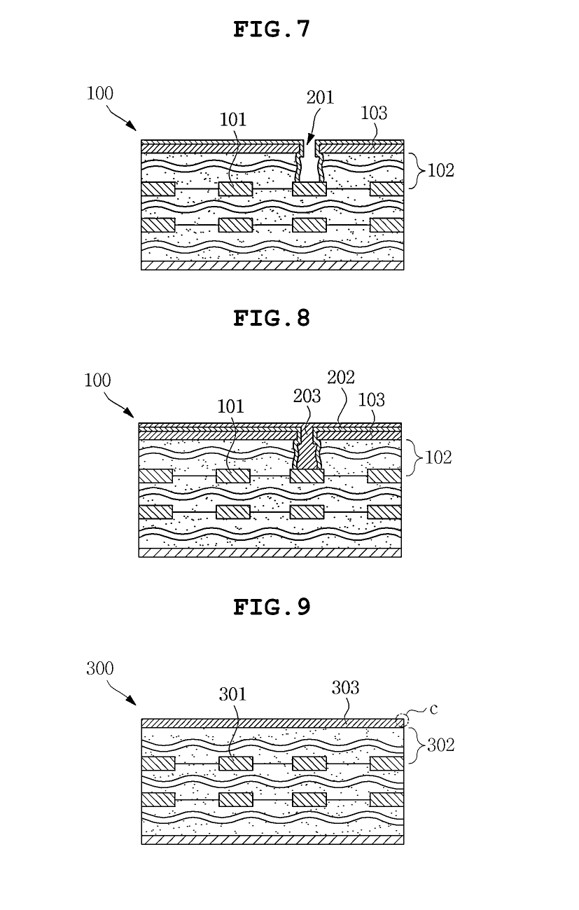

Referring to FIG. 7, an operation of forming a seed layer 202 on the surface-treated copper foil 103 of the substrate 100 having the through-hole 201 formed by the laser processing and the chemical etching processing may be further included.

The operation of forming the seed layer 202 may include an operation of removing additional residue by performing a desmear process and an operation of forming the seed layer 202 on the surface of the printed circuit substrate in which the additional residue is removed, by electroless plating.

In this case, as known in the art, the hole wall surface and the inner layer circuit are plated with the electroless plating or the electroplating, the entire surface exposed to the outside may be plated with the electroless plating at a thickness of 0.5 to 1.5 μm, and the through-hole 201 may be plated after applying a dry film to thereby expose the through-hole 201.

Referring to FIG. 8, after the operation of forming the seed layer 202, an operation of performing a plating and filling 203 filling the through-hole 201 with the electroplating may be included.

The via hole is filled with the plating and filling 203 to thereby conduct between an inner layer and an outer layer, thereby making it possible to use as the through-hole 201.

According to a typical process, the circuit is formed by patterning the seed layer 202 and the copper foil. In this case, the portion of the plating and filling 203 of the via hole may serve as the through-hole 201.

As such, since the method for forming the through-hole 201 of the multi-layered printed circuit board according to the preferred embodiment of the present invention may directly perform the laser processing on the surface-treated copper foil 103, the hole 200 is directly formed without previously forming the opening on the surface of the copper foil before the laser is radiated, such that the accuracy of the hole 200 processing is high and the laser reflectivity is low, thereby making it possible to have high efficiency in the laser processing.

In addition, after the hole 200 is bored at a desired depth by adjusting energy of the laser, the through-hole 201 may be formed.

In addition, the hole may be processed without degrading the resin and damaging the inner layer circuit 101 by a two-step processing.

Thereby, the defect concerned when the inner layer circuit 101 is over-processed by the laser may be prevented in advance.

In addition, the surface roughness is formed on the hole inner wall at the time of the to secondary process, such that the adhesion may become excellent when the plating process is performed as the following process.

### Second Preferred Embodiment

FIGS. 9 to 15 are process flow charts schematically showing a method for manufacturing a printed circuit board according to another preferred embodiment of the present invention and processes of forming a radiation hole 401 by two-step processing may be confirmed therefrom.

According to another preferred embodiment of the present invention, the method for manufacturing the printed circuit board may include an operation of preparing a substrate 300 having an insulating layer 302 and a surface-treated copper foil 303 sequentially formed on an inner layer circuit 301, an operation of forming a hole 400 by performing a primary processing for the surface-treated copper foil 303 and a part of the insulating layer 302 with laser, and an operation of forming a radiation hole 401 performing a secondary processing for the insulating layer 302 in the primarily processed hole 400 with a chemical etching liquid and removing another part of the partially removed insulating layer 302 to thereby expose the insulating layer 302.

Referring to FIG. 9, the operation of preparing the substrate 300 may include an operation of preparing a printed circuit board including the inner layer circuit 301, an operation of laminating the insulating layer 302 on the printed circuit board, and an operation of laminating the surface-treated copper foil 303 on the insulating layer 302.

Here, the substrate 300, which is a circuit substrate on which at least one layer of circuit including a connection pad is formed on the insulating layer, may be a printed circuit board.

Although a configuration of a specific inner layer circuit is omitted in FIG. 9 for convenience of explanation, it may be easily appreciated by those skilled in the art that a typical printed circuit board having at least one layer of circuit formed on the insulating layer may be used as the substrate 300.

As the insulating layer, a resin insulating layer may be used.

As a material of the resin insulating layer, a thermo-setting resin such as an epoxy resin, a thermo-plastic resin such as a polyimide resin, a resin having a reinforcement material such as a glass fiber or an inorganic filler impregnated in the thermo-setting resin and the thermo-plastic resin, for example, a prepreg may be used. In addition, a thermo-setting resin, a photo-curable resin, and the like, may be used. However, the material of the resin insulating layer is not specifically limited thereto.

When cutting a cross-section of the insulating layer, the reinforcement material may be exposed.

The circuit layer may be used without being limited as long as it is used as a conductive metal for a circuit in a field of a circuit board. In the printed circuit board, copper may be typically used.

The inner layer circuit 301 according to the preferred embodiment of the present invention may be a circuit layer formed to have a thickness 0.5 to 40 μm on the copper foil by plating.

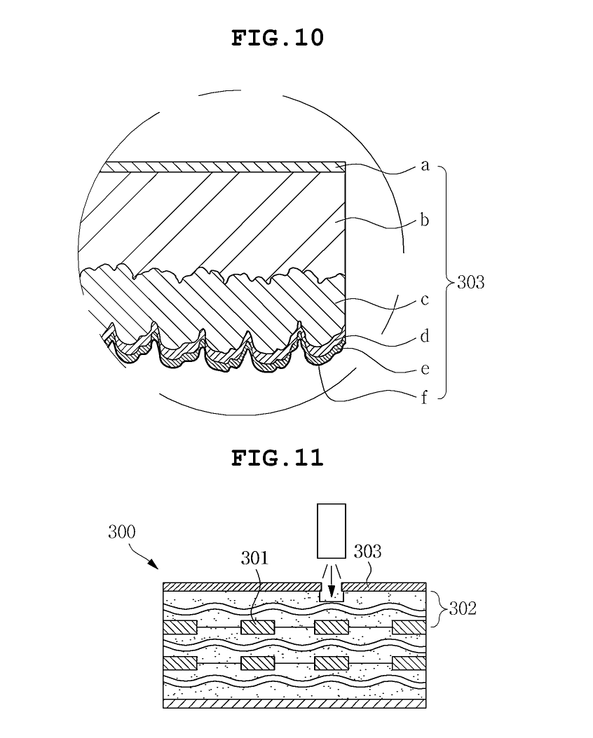

Referring to FIG. 10, which is an enlarged view of a part C of FIG. 9, a sequential process order of the following operations a to f, which is an operation of forming the surface-treated copper foil 303 may be appreciated.

a) As an operation of applying triazole compound on a support layer to form an organic delamination layer and forming a nickel layer on the organic delamination layer at a thin thickness of 0.08 to 2 μm by electroplating, delamination property between the support layer and the surface-treated copper foil is increased. The organic delamination layer and the nickel layer 330-a may decrease reflectivity and increase an accuracy of processability of the hole 400.

b) As an operation of forming a copper bulk layer 303-b having a thickness of 1 to 3 μm on the nickel layer by surface-treating with the electroplating, a copper content is highest and the copper content of the surface-treated copper foil 303 may be 90% or more.

c) An operation of attaching copper particles on the copper bulk layer 303-b to form a copper nodule layer 303-c allows the copper particles stacked on the bulk layer to be stuck in the insulating layer to thereby increase adhesion property with an insulating material.

d) As an operation of forming a metal layer 303-d consisting of zinc, nickel, or a combination thereof in the copper nodule layer 303-c, heat-resisting property and hydrochloric acid-resisting property of the copper nodule layer may be increased.

e) An operation of forming chromate layer 303-e on the metal layer 303-d increases anti-tarnish property.

f) In an operation of forming a silane compound in the chromate layer 303-e, a silane layer 303-f improving physical and chemical coupling with the insulating material may be formed.

A method for surface-treating the surface-treated copper foil 303 is basically performed in a water tank including metallic salts and may adjust a concentration pH, a temperature, and a current density of the metallic salt to thereby form the copper foil at a desired thickness.

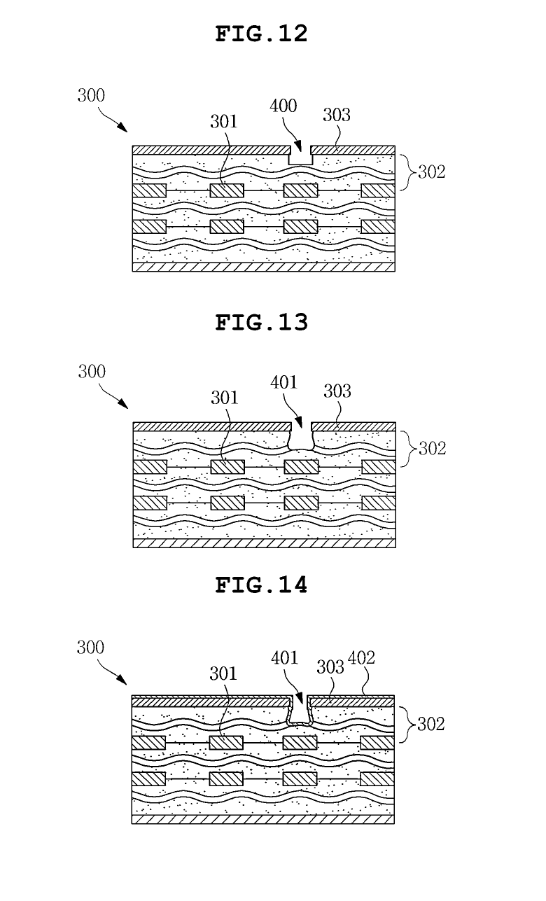

Referring to FIGS. 11 to 12, as an operation of forming a hole 400 performing a primary processing for the surface-treated copper foil 303 and a part of the insulating layer 302 with the laser to thereby expose the insulating layer 302, the radiation hole 401 performing a radiation function may be manufactured.

The laser energy may be adjusted by changing laser power, repetition rate, and a spot size.

In the operation of forming of the hole 400 of the method for manufacturing the printed circuit board, the laser processing may rapidly form the hole 400 in an organic material such as an epoxy resin, a polyimide resin, or the like, such that it has been widely used in manufacturing to the multi-layered printed circuit board. However, since the existing copper foil surface reflects laser beam, the method for surface-treating the copper foil for solving this problem has been proposed in the present invention.

The primary laser processing of the present invention may use CO₂, YAG/UV, Pico, and excimer lasers, but the present invention does not particularly limit the kind of lasers.

Here, the operation of forming the hole 400 may be performed by setting a laser processing condition so that the surface roughness of the inner layer circuit 301 is 0.05 to 0.6 μm.

In addition, the operation of forming the hole 400 is performed by setting the processing condition to a degree which does not damage the inner layer circuit 301, and a thickness of an unprocessed resin becomes generally a thickness of a butter coat of about 0.2 to 5 μm. The butter coat refers to a resin layer of a part of the insulating material including glass fabric and is the resin layer from a surface of the glass fabric to a surface of the insulating material.

Referring to FIG. 13, the insulating layer 302 in the hole 400 which is primarily processed with the laser is secondarily processed with an etching liquid, thereby making it possible to form the radiation hole 401 having a desired depth.

Referring to FIG. 14, an operation of forming a seed layer 402 on the surface-treated copper foil 303 of the substrate 300 having the radiation hole 401 formed by the secondary processing may be further included.

The operation of forming the seed layer 402 may include an operation of removing additional residue by performing a desmear process and an operation of forming the seed layer 402 on the surface of the substrate 300 in which the additional residue is removed, by electroless plating.

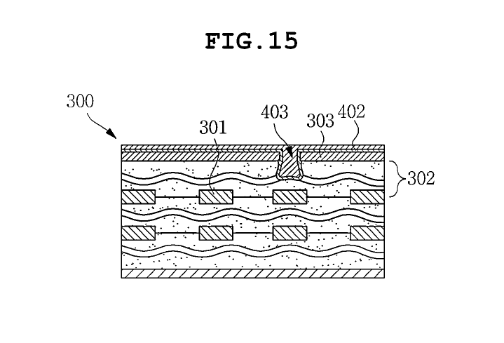

Referring to FIG. 15, after the operation of forming the seed layer 402, an operation of performing a plating and filling 403 filling the radiation hole 401 with the electroplating may be included.

According to a typical process, the circuit is formed by patterning the seed layer 402 and the copper foil. In this case, the portion of the plating and filling 403 of the via hole may serve as the radiation hole 401.

As such, since the method for forming the radiation hole 401 of the multi-layered printed circuit board according to another preferred embodiment of the present invention may directly perform the laser processing on the surface-treated copper foil, the hole 400 is directly formed without previously forming the opening on the surface of the copper foil before the laser is radiated, such that the accuracy of the hole 400 processing is high and the laser reflectivity is low, thereby making it possible to have high efficiency in the laser processing.

In addition, after the hole 400 is bored at a desired depth by adjusting energy of the laser, the radiation hole 401 may be formed.

In addition, the hole may be processed without degrading the resin and damaging the inner layer circuit 301 by a two-step processing.

Thereby, the defect concerned when the inner layer circuit 301 is over-processed by the laser may be prevented in advance.

In addition, the surface roughness is formed on the hole inner wall at the time of the secondary process, such that the adhesion may become excellent when the plating process is performed as the following process.

With the method for forming the hole of the multi-layered printed circuit board according to the preferred embodiment of the present invention, since the laser process may be directly performed on the surface-treated copper foil, the hole is directly formed without previously forming the opening on the surface of the copper foil before the laser is irradiated, such that the accuracy of the hole process is high and the laser reflectivity is low, thereby making it possible to have high efficiency in the laser process.

In addition, after the hole is bored at a desired depth by adjusting energy of the laser, the holes of the desired purpose such as a through-hole, a radiation hole, and the like may be formed.

In addition, the hole may be machined without degrading the resin and the damaging the inner layer circuit by a two-step process.

Thereby, the defect concerned when the inner layer circuit is over-processed by the laser may be prevented in advance.

In addition, the surface roughness is formed on the inner wall of the hole at the time of the secondary process, such that the adhesion may become excellent when the plating process is performed as the following process.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims

What is claimed is:

1. A method for manufacturing a multi-layered printed circuit board, the method comprising:
an operation of preparing a substrate having an insulating layer and a surface-treated copper foil sequentially formed on an inner layer circuit;
an operation of forming a hole exposing the insulating layer by performing a primary processing for the surface-treated copper foil and a part of the insulating layer with laser; and
an operation of forming a through-hole exposing the inner layer circuit by performing a secondary processing for the exposed insulating layer with a chemical etching liquid.

2. The method as set forth in claim 1, wherein the operation of preparing the substrate includes:
an operation of preparing a printed circuit board including the inner layer circuit;
an operation of laminating the insulating layer on the printed circuit board; and
an operation of laminating the surface-treated copper foil on the insulating layer.

3. The method as set forth in claim 1, wherein the surface-treated copper foil is formed by:
an operation of applying triazole compound on a support layer to form an organic delamination layer and forming a nickel layer on the organic delamination layer at a thin thickness of 0.08 to 2 μm by electroplating;
an operation of forming a copper bulk layer having a thickness of 1 to 3 μm on the nickel layer by surface-treating with the electroplating;
an operation of attaching copper particles on the copper bulk layer to thereby form a copper nodule layer;
an operation of forming a metal layer consisting of zinc, nickel, or a combination thereof in the copper nodule layer;
an operation of forming a chromate layer on the metal layer; and
an operation of forming a silane compound in the chromate layer.

4. The method as set forth in claim 1, wherein the laser used in the primary processing forming the hole is at least one of CO₂, YAG/UV, Pico, and excimer laser.

5. The method as set forth in claim 1, wherein the chemical etching liquid used in the secondary processing forming the hole is one or a mixture of two or more of hydroxyl radical, concentrated sulfuric acid, sulfate radical, ozone, sodium peroxysulfate, hydrogen peroxide, potassium permanganate, sodium salts permanganate, and chromic acid.

6. The method as set forth in claim 1, further comprising, after the operation of forming the through-hole, an operation of forming a seed layer on the surface-treated copper foil of the substrate having the through-hole formed therein.

7. The method as set forth in claim 6, wherein the operation of forming the seed layer includes:
an operation of performing a desmear process to thereby remove residue; and
an operation of forming the seed layer on a surface of the substrate in which the residue is removed by electroless plating.

8. The method as set forth in claim 6, further comprising, after the operation of forming the seed layer, an operation of filling the through-hole with the electroplating.

9. A method for manufacturing a multi-layered printed circuit board, the method comprising:
an operation of preparing a substrate having an insulating layer and a surface-treated copper foil sequentially formed on an inner layer circuit;
an operation of forming a hole by performing a primary processing for the surface-treated copper foil and a part of the insulating layer with laser; and
an operation of forming a radiation hole by performing a secondary processing for the insulating layer in the primarily processed hole with a chemical etching liquid and removing another part of the partially removed insulating layer to thereby expose the insulating layer.

10. The method as set forth in claim 9, wherein the operation of preparing the substrate includes:
an operation of preparing a printed circuit board including the inner layer circuit;
an operation of laminating the insulating layer on the printed circuit board; and
an operation of laminating the surface-treated copper foil on the insulating layer.

11. The method as set forth in claim 9, wherein the surface-treated copper foil is formed by:
an operation of applying triazole compound on a support layer to form an organic delamination layer and forming a nickel layer on the organic delamination layer at a thin thickness of 0.08 to 2 μm by electroplating;
an operation of forming a copper bulk layer having a thickness of 1 to 3 μm on the nickel layer by surface-treating with the electroplating;
an operation of attaching copper particles on the copper bulk layer to thereby form a copper nodule layer;
an operation of forming a metal layer consisting of zinc, nickel, or a combination thereof in the copper nodule layer;
an operation of forming a chromate layer on the metal layer; and
an operation of forming a silane compound in the chromate layer.

12. The method as set forth in claim 9, wherein the laser used in the primary processing forming the hole is at least one of CO₂, YAG/UV, Pico, and excimer laser.

13. The method as set forth in claim 9, wherein the chemical etching liquid used in the secondary processing forming the hole is one or a mixture of two or more of hydroxyl radical, concentrated sulfuric acid, sulfate radical, ozone, sodium peroxysulfate, hydrogen peroxide, potassium permanganate, sodium salts permanganate, and chromic acid.

14. The method as set forth in claim 9, further comprising, after the operation of forming the radiation hole, an operation of forming a seed layer on the surface-treated copper foil of the printed circuit board having the radiation hole formed therein.

15. The method as set forth in claim 14, wherein the operation of forming the seed layer includes:
an operation of performing a desmear process to thereby remove residue; and
an operation of forming the seed layer on a surface of the printed circuit board in which the residue is removed by electroless plating.

16. The method as set forth in claim 14, further comprising, after the operation of forming the seed layer, an operation of filling the radiation-hole with the electroplating.
